(19) United States
(12) Patent Application Publication
(10) Pub. No.: US 2023/0176199 A1
(43) Pub. Date: Jun. 8, 2023

(54) SPATIAL FILTERING FOR SCANNING LIDAR WITH MICRO SHUTTER ARRAY

(71) Applicant: BEIJING VOYAGER TECHNOLOGY CO., LTD., Beijing (CN)

(72) Inventors: Yue Lu, Los Gatos, CA (US); Youmin Wang, Berkeley, CA (US)

(73) Assignee: BEIJING VOYAGER TECHNOLOGY CO., LTD., Beijing (CN)

(21) Appl. No.: 17/544,923

(22) Filed: Dec. 7, 2021

(51) Int. Cl. G01S 7/4863; B81B 7/04; G02B 26/02; G02B 26/08; G01S 17/931

(52) U.S. Cl. CPC G01S 7/4863; B81B 7/04; G01S 17/931; G02B 26/02; G02B 26/0841

(57) ABSTRACT

Embodiments of the disclosure provide a micro shutter array, an optical sensing system, and an optical sensing method. The optical sensing system includes a laser emitter configured to sequentially emit a series of optical signals and a steering device configured to direct the series of optical signals in different directions towards an environment surrounding the optical sensing system. The optical sensing system further includes a receiver configured to receive the series of optical signals returning from the environment. The receiver includes a micro shutter array disposed in a light path of the returning optical signals and configured to sequentially open only a portion of the micro shutter array at a specified location at each time point, to allow the returned series of optical signals to sequentially pass through the micro shutter array. The receiver further includes a photodetector configured to receive the optical signals sequentially passed through the micro shutter array.

### TECHNICAL FIELD

The present disclosure relates to a light detection and ranging (LiDAR) system, and more particularly to, a micro shutter array for filtering out ambient light when detecting optical signals in a scanning LiDAR system.

### BACKGROUND

In a scanning LiDAR system, a biaxial architecture has some advantages such as simpler optics, less limitation on a scanner, and a larger aperture which is not limited to the scanner size. One requirement of the biaxial architecture though is that the field of view (FOV) of the receiving optics has to be large enough to cover all scanned points in the far field. However, if the receiving optics is made to be large, in real-world LiDAR applications, it will also collect a large amount of ambient light, such as light from the direct or indirect sunlight reflected off far-field objects. The larger the receiving FOV, the more collected ambient light. Ambient light introduces noises for backend processing and thus lowers the detection accuracy. Therefore, there is a trade-off between the receiving FOV that affects the detection range and the signal-to-noise ratio that affects the detection accuracy in existing biaxial scanning LiDAR systems.

Embodiments of the disclosure address the above problems by including a micro shutter array for filtering out the ambient light when detecting the optical signals in a biaxial scanning LiDAR system.

### SUMMARY

Embodiments of the disclosure provide an exemplary optical sensing system. The optical sensing system includes a laser emitter configured to sequentially emit a series of optical signals and a steering device configured to direct the series of optical signals in different directions towards an environment surrounding the optical sensing system. The optical sensing system further includes a receiver configured to receive the series of optical signals returning from the environment. The receiver includes a micro shutter array disposed in a light path of the returning series of optical signals and configured to sequentially open only a portion of the micro shutter array at a specified location at each time point, to allow the returned series of optical signals to sequentially pass through the micro shutter array. The receiver further includes a photodetector configured to receive the optical signals sequentially passed through the micro shutter array.

Embodiments of the disclosure also provide an exemplary optical sensing method using a micro shutter array. The method includes sequentially emitting, by a laser emitter of an optical sensing system, a series of optical signals. The method further includes directing, by a steering device of the optical sensing system, the series of optical signals in different directions towards an environment surrounding the optical sensing system. The method additionally includes receiving the series of optical signals returned from the environment, by a micro shutter array disposed in a light path of the returning optical signals, where the micro shutter array sequentially opens only a portion of the micro shutter array at a specified location at each time point, to allow the returned series of optical signals to sequentially pass through the micro shutter array. The method additionally includes receiving, by a photodetector, the optical signals sequentially passed through the micro shutter array.

Embodiments of the disclosure further provide an exemplary receiver of an optical sensing system. The exemplary receiver includes a micro shutter array disposed in a light path of returning series of optical signals and configured to sequentially open only a portion of the micro shutter array at a specified location at each time point, to allow the returned series of optical signals to sequentially pass through the micro shutter array. The exemplary micro shutter array further includes a photodetector configured to receive the optical signals sequentially passed through the micro shutter array.

It is to be understood that both the foregoing general description and the following detailed description are exemplary and explanatory only and are not restrictive of the present disclosure, as claimed.

### BRIEF DESCRIPTION OF THE DRAWINGS

FIG. 1 illustrates a schematic diagram of an exemplary vehicle equipped with a LiDAR system containing a micro shutter array, according to embodiments of the disclosure.

FIG. 2 illustrates a block diagram of an exemplary LiDAR system containing a micro shutter array, according to embodiments of the disclosure.

FIG. 3 illustrates a block diagram of another exemplary LiDAR system containing a micro shutter array, according to embodiments of the disclosure.

FIG. 4 illustrates a schematic diagram of an exemplary operation of a micro shutter array, according to embodiments of the disclosure.

FIG. 5 illustrates a schematic diagram of an exemplary view of sequentially opened micro shutter elements in a micro shutter array, according to embodiments of the disclosure.

FIG. 6 illustrates a schematic diagram of another exemplary view of sequentially opened micro shutter elements in a micro shutter array, according to embodiments of the disclosure.

FIG. 7 illustrates a schematic diagram of an exemplary control mechanism for controlling a micro shutter array, according to embodiments of the present disclosure.

FIG. 8 is a flow chart of an exemplary optical sensing method of a LiDAR system containing a micro shutter array, according to embodiments of the disclosure.

### DETAILED DESCRIPTION

Reference will now be made in detail to the exemplary embodiments, examples of which are illustrated in the accompanying drawings. Wherever possible, the same reference numbers will be used throughout the drawings to refer to the same or like parts.

Embodiments of the present disclosure provide a micro shutter array in a receiver of a biaxial scanning LiDAR system. According to one example, the micro shutter array may be disposed between a receiving lens and a condenser lens of the receiver. The micro shutter array may include a plurality of micro shutter elements arranged in a one-dimensional, two-dimensional, or three-dimensional array, where each micro shutter element may be controlled to switch between an open and a closed state. Accordingly, when an optical signal returned from the environment of the LiDAR system is received by the receiver in a biaxial scanning LiDAR system, the micro shutter array may be controlled to allow only a spatially selected portion to be opened, to allow the returned optical signal to pass through the spatially selected portion of the micro shutter array and detected by a photodetector of the receiver.

In some embodiments, the spatially selected portion is selected based on the location where the returned optical signal is incident on the micro shutter array after collimation by the receiving lens, where the incident location of the returned optical signal is also determined by the angular direction at which a scanner of the LiDAR system is pointing during a scanning process. Accordingly, when the scanner of the LiDAR system scans the environment by continuously changing the angular direction, the location where the returned optical signal is incident on the micro shutter array may also continuously change, and the changing pattern may correspond to a pattern that the scanner of the LiDAR system follows during the scanning process. To allow the returned optical signals to pass through the micro shutter array, the micro shutter array may be then controlled to sequentially open different portions of the micro shutter array, where each portion is spatially selected based on the location where the returned optical signal is incident on the micro shutter array.

In some embodiments, the micro shutter array may be coated with a reflective material that has a high reflectivity. Accordingly, by controlling the micro shutter array to sequentially open only a spatially selected portion at each time point during a scanning process, the majority of the micro shutter array remains closed during the scanning process. Therefore, most of the ambient light, including the direct or indirect sunlight reflected off far-field objects, may be reflected back without passing through the micro shutter array for detection by the photodetector of the LiDAR system. This then allows the signal-to-ratio to remain high for a biaxial LiDAR system, even when the receiving optics FOV is large. That is, the detection range of the disclosed biaxial scanning LiDAR system can be increased without the sacrifice of detection accuracy of the LiDAR system. Other advantages of the disclosed micro shutter array include its easy integration into the existing biaxial scanning LiDAR systems, without changing many of the other components, especially the transmitting part included in these LiDAR systems. The features and advantages described herein are not exhaustive and many additional features and advantages will be apparent to one of ordinary skill in the art in view of the drawings and the following descriptions.

The disclosed LiDAR system containing a micro shutter array can be used in many applications. For example, the disclosed LiDAR system can be used in advanced navigation technologies, such as to aid autonomous driving or to generate high-definition maps, in which the optical sensing system can be equipped on a vehicle.

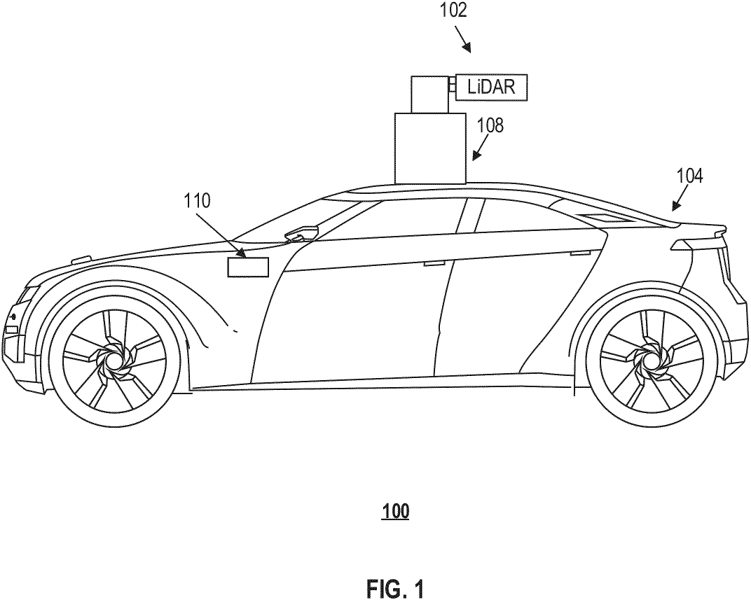

FIG. 1 illustrates a schematic diagram of an exemplary vehicle equipped with an optical sensing system containing a micro shutter array, according to embodiments of the disclosure. Consistent with some embodiments, vehicle 100 may be a survey vehicle configured for acquiring data for constructing a high-definition map or 3-D buildings and city modeling. Vehicle 100 may also be an autonomous driving vehicle.

As illustrated in FIG. 1, vehicle 100 may be equipped with an optical sensing system, e.g., a LiDAR system 102 mounted to a body 104 via a mounting structure 108. Mounting structure 108 may be an electro-mechanical device installed or otherwise attached to body 104 of vehicle 100. In some embodiments of the present disclosure, mounting structure 108 may use screws, adhesives, or another mounting mechanism. Vehicle 100 may be additionally equipped with a sensor 110 inside or outside body 104 using any suitable mounting mechanisms. Sensor 110 may include sensors used in a navigation unit, such as a Global Positioning System (GPS) receiver and one or more Inertial Measurement Unit (IMU) sensors. It is contemplated that the manners in which LiDAR system 102 or sensor 110 can be equipped on vehicle 100 are not limited by the example shown in FIG. 1 and may be modified depending on the types of LiDAR system 102 and sensor 110 and/or vehicle 100 to achieve desirable 3D sensing performance.

Consistent with some embodiments, LiDAR system 102 and sensor 110 may be configured to capture data as vehicle 100 moves along a trajectory. For example, a scanning system of LiDAR system 102 may be configured to scan the surrounding environment. LiDAR system 102 measures distance to a target by illuminating the target with laser beams and measuring the reflected/scattered pulses with a receiver. The laser beams used for LiDAR system 102 may be ultraviolet, visible, or near-infrared, and may be pulsed or continuous wave laser beams. In some embodiments of the present disclosure, LiDAR system 102 may capture point cloud data including depth information of the objects in the surrounding environment, which may be used for constructing a high-definition map or 3-D buildings and city modeling. As vehicle 100 moves along the trajectory, LiDAR system 102 may continuously capture data including the depth information of the surrounding objects (such as moving vehicles, buildings, road signs, pedestrians, etc.) for map, building, or city modeling construction.

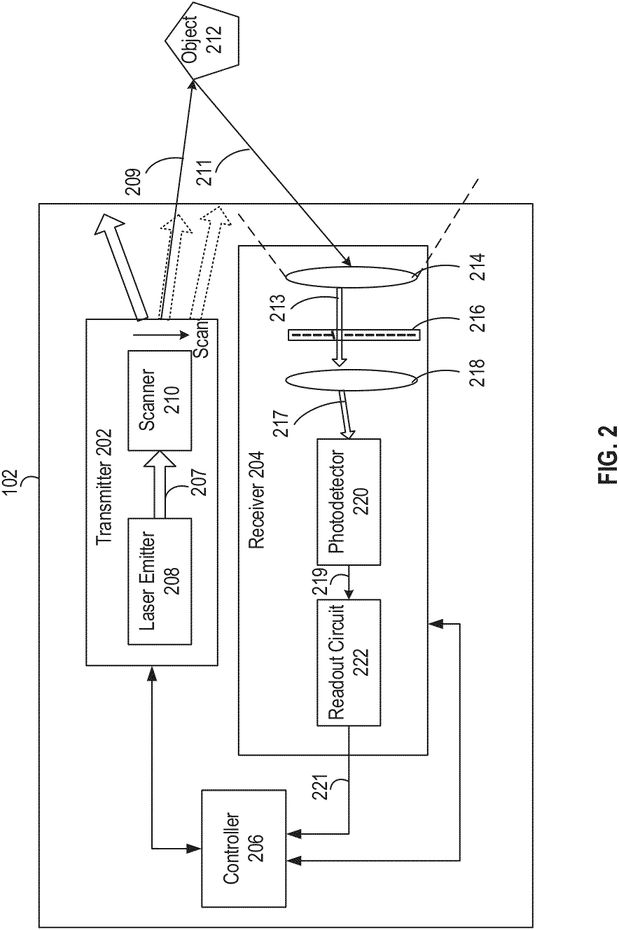

FIG. 2 illustrates a block diagram of an exemplary LiDAR system containing a micro shutter array, according to embodiments of the disclosure. In some embodiments, LiDAR system 102 may be a biaxial LiDAR, a semi-coaxial LiDAR, a coaxial LiDAR, a scanning flash LiDAR, etc. As illustrated, LiDAR system 102 may include a transmitter 202, a receiver 204, and a controller 206 coupled to transmitter 202 and receiver 204. Transmitter 202 may further include a laser emitter 208 for emitting a laser beam 207, and one or more optics (not shown) for collimating laser beam 207 emitted by laser emitter 208. In some embodiments, transmitter 202 may additionally include a scanner 210 for steering the collimated laser beam according to a certain pattern. Transmitter 202 may emit optical beams (e.g., pulsed laser beams, continuous wave (CW) beams, frequency modulated continuous wave (FMCW) beams) along multiple directions. Receiver 204 may further include a receiving lens 214, a micro shutter array 216, a condenser lens 218, a photodetector 220, and a readout circuit 222.

Laser emitter 208 may be configured to emit laser beams 207 (also referred to as “native laser beams”) to scanner 210. For instance, laser emitter 208 may generate laser beams in the ultraviolet, visible, or near-infrared wavelength range, and provide the generated laser beams to scanner 210. In some embodiments of the disclosure, depending on underlying laser technology used for generating laser beams, laser emitter 208 may include one or more of a double heterostructure (DH) laser emitter, a quantum well laser emitter, a quantum cascade laser emitter, an interband cascade (ICL) laser emitter, a separate confinement heterostructure (SCH) laser emitter, a distributed Bragg reflector (DBR) laser emitter, a distributed feedback (DFB) laser emitter, a vertical-cavity surface-emitting laser (VCSEL) emitter, a vertical-external-cavity surface-emitting laser (VECSEL) emitter, an extern-cavity diode laser emitter, etc., or any combination thereof. Depending on the number of laser emitting units in a package, laser emitter 208 may include a single emitter containing a single light-emitting unit, a multi-emitter unit containing multiple single emitters packaged in a single chip, an emitter array or laser diode bar containing multiple (e.g., 10, 20, 30, 40, 50, etc.) single emitters in a single substrate, an emitter stack containing multiple laser diode bars or emitter arrays vertically and/or horizontally built up in a single package, etc., or any combination thereof. Depending on the operating time, laser emitter 208 may include one or more of a pulsed laser diode (PLD), a CW laser diode, a Quasi-CW laser diode, etc., or any combination thereof. Depending on the semiconductor materials of diodes in laser emitter 208, the wavelength of emitted laser beams 207 may be at different values, such as 760 nm, 785 nm, 808 nm, 848 nm, 870 nm, 905 nm, 940 nm, 980 nm, 1064 nm, 1083 nm, 1310 nm, 1370 nm, 1480 nm, 1512 nm, 1550 nm, 1625 nm, 1654 nm, 1877 nm, 1940 nm, 2000 nm, etc. It is understood that any suitable laser source may be used as laser emitter 208 for emitting laser beams 207 at a proper wavelength.

Scanner 210 may include various optical elements such as prisms, mirrors, gratings, optical phased array (e.g., liquid crystal-controlled grating), or any combination thereof. When a laser beam is emitted by laser emitter 208, scanner 210 may direct the emitter laser beam towards the environment, e.g., object(s) 212, surrounding LiDAR system 102. In some embodiments, object(s) 212 may be made of a wide range of materials including, for example, non-metallic objects, rocks, rain, chemical compounds, aerosols, clouds, and even single molecules. In some embodiments, at each time point during a scanning process, scanner 210 may direct laser beams 209 to object(s) 212 in a direction within a range of scanning angles by rotating a deflector, such as a micromachined mirror assembly.

Receiver 204 may be configured to detect returned laser beams 211 reflected by object(s) 212. Upon contact, laser light can be reflected/scattered by object(s) 212 via backscattering, such as Raman scattering, and fluorescence. Returned laser beams 211 may be in a same or different direction from laser beams 209. In some embodiments, receiver 204 may collect laser beams returned from object(s) 212 and output signals reflecting the intensity of the returned laser beams.

As described above and as illustrated in FIG. 2, receiver 204 may include a receiving lens 214, a micro shutter array 216, a condenser lens 218, a photodetector 220, and a readout circuit 222. Receiving lens 214 may receive laser beams 211 returned from the environment (e.g., reflected by object(s) 212) and ambient light from the environment, and may collimate the receiving laser beams and ambient light towards micro shutter array 216. Micro shutter array 216 may filter out the majority of the ambient light from the collimated laser beams 213, to allow only the collimated laser beams and a very limited amount of the ambient light to pass through the micro shutter array. For instance, micro shutter array 216 may open only a very small portion at a position where a returned laser beam is incident on the micro shutter array at each time point, to allow the returned laser beam and a very limited amount of the ambient light, if any, to pass through. Condenser lens 218 may be configured to converge and focus a passed-through laser beam on photodetector 220 as a focused spot 217.

Photodetector 220 may be configured to detect the focused laser spot 217. In some embodiments, photodetector 220 may include a single sensor element that continuously detects the focused laser spots passed through micro shutter array 216 and focused by condenser lens 218. In some embodiments, photodetector 220 may be a photosensor array that includes multiple sensor elements. Different focused laser spots 217 may be detected by different sensor elements included in the photosensor array. In some embodiment, a focused laser spot detected by photodetector 220 may be converted into an electrical signal 219 (e.g., a current or a voltage signal). Electrical signal 219 may be an analog signal which is generated when photons are absorbed in a photodiode included in photodetector 220. In some embodiments, photodetector 220 may be a PIN detector, an avalanche photodiode (APD) detector, a single photon avalanche diode (SPAD) detector, a silicon photo multiplier (SiPM) detector, or the like.

Readout circuit 222 may be configured to integrate, amplify, filter, and/or multiplex signal detected by photodetector 220 and transfer the integrated, amplified, filtered, and/or multiplexed signal 221 onto an output port (e.g., controller 206) for readout. In some embodiments, readout circuit 222 may act as an interface between photodetector 220 and a signal processing unit (e.g., controller 206). Depending on the configurations, readout circuit 222 may include one or more of a transimpedance amplifier (TIA), an analog-to-digital converter (ADC), a time-to-digital converter (TDC), or the like.

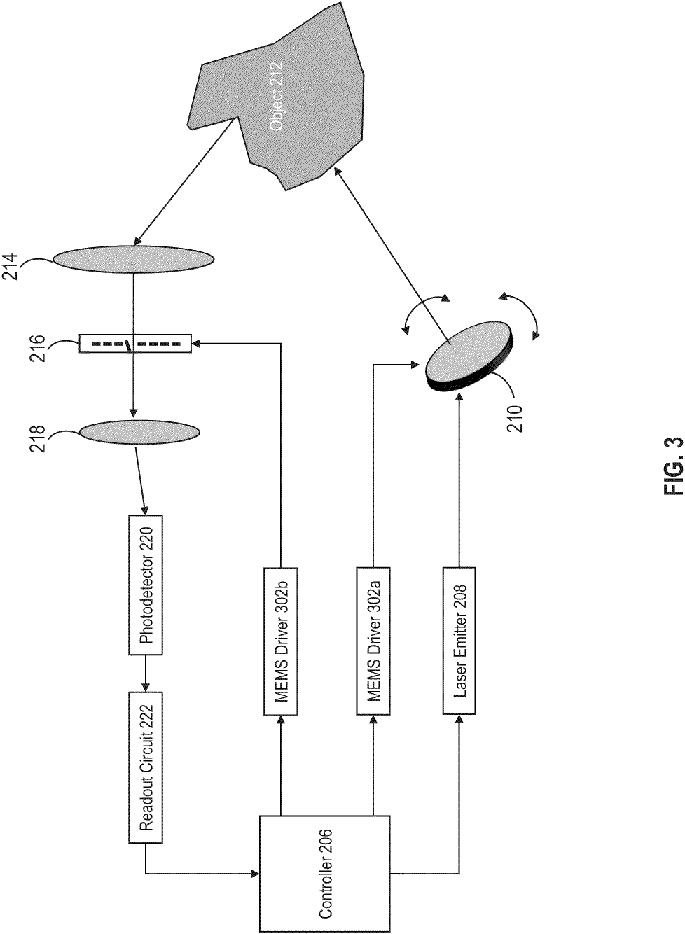

Controller 206 may be configured to control transmitter 202 and/or receiver 204 to perform detection/sensing operations. For instance, controller 206 may control laser emitter 208 to emit laser beams 207, or control photodetector 220 to detect optical signal returning from the environment. In some embodiments, controller 206 may also control data acquisition and perform data analysis. For instance, controller 206 may collect digitalized signal information from readout circuit 222, determine the distance of object(s) 212 from LiDAR system 102 according to the travel time of laser beams, and construct a high-definition map or 3-D buildings and city modeling surrounding LiDAR system 102 based on the distance information of object(s) 212. In some embodiments, controller 206 may combine the digitalized signals from a series of laser beams passed through different portions of micro shutter array 216 in constructing a high-definition map or 3-D buildings and city modeling surrounding LiDAR system 102. The specific details regarding the pass-through of micro shutter array 216 by a series of laser beams will be described hereinafter in conjunction with FIGS. 3-8.

FIG. 3 illustrates a block diagram of another exemplary LiDAR system 102 containing a micro shutter array, according to embodiments of the disclosure. As illustrated, LiDAR system 102 may include a scanner 210 coupled to a laser emitter 208. In addition, LiDAR system 102 may also include a micro-electromechanical system (MEMS) driver 302a that drives scanner 210 to rotate. A controller 206 may provide a control signal to MEMS driver 302a for controlling the rotation of scanner 210 to achieve two-dimensional scanning. For instance, controller 206 may control scanner 210 to steer laser beams emitted by laser emitter 208 towards an object(s) 212, which may be a far-field object surrounding LiDAR system 102.

As illustrated, LiDAR system 102 may further include a receiving lens 214, a condenser lens 218, and a micro shutter array 216 disposed between receiving lens 214 and condenser lens 218. In addition, LiDAR system 102 may also include a photodetector 220 and readout circuit(s) 222, which is coupled to controller 206. In some embodiments, LiDAR system 102 may further include a MEMS driver 302b coupled to micro shutter array 216, where MEMS driver 302b may drive the micro shutter elements included in micro shutter array 216 to individually open or close according to a predefined pattern, as further described below.

Receiving lens 214 may collimate the optical signals received from the environment. In some embodiments, to improve the detection range of LiDAR system 102, e.g., to detect a building that is 100 m or higher surrounding the LiDAR system, the FOV of receiving lens 214 may be configured to be large. With the increased FOV, when receiving the optical signals from the environment, besides the laser beams reflected from objects (e.g., far-field object(s) 212), receiving lens 214 may also receive a large amount of ambient light from the environment. For instance, direct or indirect sunlight reflected off far-field objects may be also received by receiving lens 214. The larger the FOV of the receiving lens, the more ambient light received from the environment, which introduces more noise for backend processing. Accordingly, the detection accuracy is reduced if more ambient light is detected by photodetector 220 of LiDAR system 102.

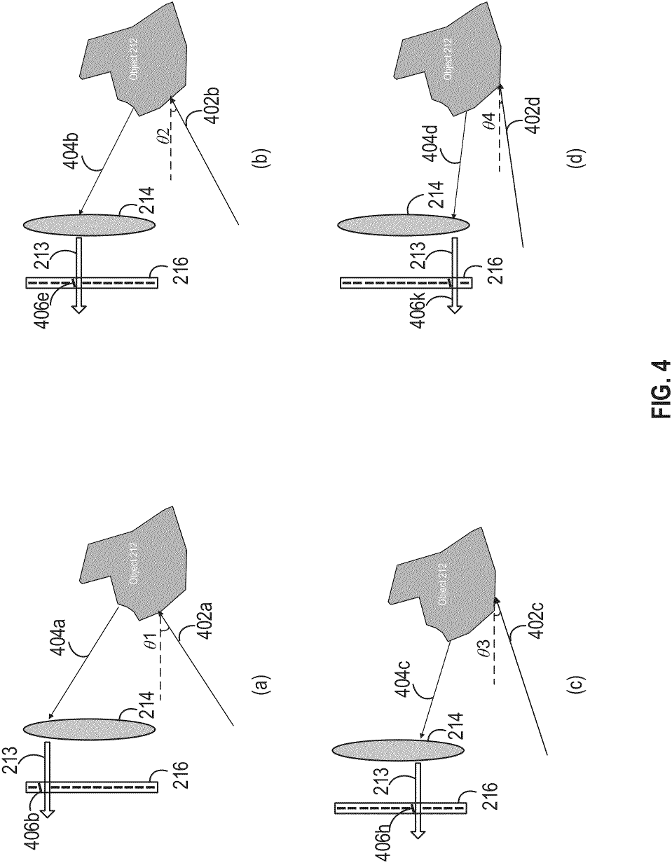

By blocking the ambient light from being detected by photodetector 220, micro shutter array 216 may increase the detection accuracy of LiDAR system 102 even when the FOV of the receiving lens is large. As illustrated, micro shutter array 216 may be disposed along the light path of the returned optical signals right after receiving lens 214. The optical signals, including the returned laser beams and the ambient light, may be collimated and directed by receiving lens 214 towards micro shutter array 216. Micro shutter array 216 may serve as a filter to allow the returned laser beams to pass through while blocking most of the ambient light. To achieve such a filtering effect, micro shutter array 216 may include a plurality of micro shutter elements arranged in a two-dimensional array, where each micro shutter element may include a coated reflective surface facing receiving lens 214. A micro shutter element can be in one of an open state for allowing light and laser beams to pass through or in a closed state for blocking light and laser beams to pass through. At any moment during a scanning process, the majority of the micro shutter elements may remain closed and thus the majority of the ambient light may be reflected back towards receiving lens 214. Only a spatially selected portion of micro shutter elements may be in an open state for allowing the returned laser beams to pass through the micro shutter array. A very limited portion of the ambient light, if any, may also pass through the spatially selected portion of the micro shutter elements in the open state. The spatial location of the selectively opened portion may correspond to the incident position of the returned laser beam, which may be further determined by the angular direction at which a scanner of the LiDAR system is pointing during a scanning process, as further described in detail in FIG. 4.

FIG. 4 illustrates a schematic diagram of an exemplary operation of a micro shutter array, according to embodiments of the disclosure. As illustrated, micro shutter array 216 may sit on a light path of the optical signals returning from the environment. The optical signals impinging on receiving lens 214 may be first collimated onto micro shutter array 216, where the optical signals may include both the returned laser beams and the ambient light. A small portion of micro shutter array 216 may be controlled to open only when a returned laser beam is incident on that portion. In one example, as illustrated in parts (a)-(d) in FIG. 4, when returned laser beams are incident at different positions on the micro shutter array at different time points during a scanning process, the micro shutter element(s) corresponding to that position may be controlled to open. The exact position where the returned laser beam is incident on the micro shutter array at each time point may be determined by the angular direction or the incident angle at which the scanner of the LiDAR system is pointing at a far-field object at that time point during the scanning process.

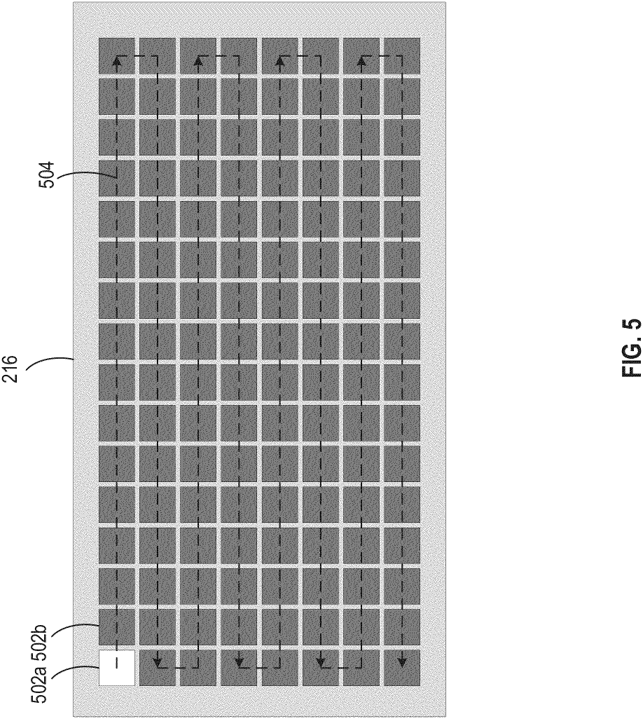

For instance, in part (a) of FIG. 4, at time point t1 of a scanning process, the angular direction (or incident angle) at which the scanner of the LiDAR system is pointing at object(s) 212 is indicated by arrow 402a (or incident angle θ1). The returned laser beam reflected off far-field object(s) 212 is indicated by arrow 404a, which, after collimation by the receiving lens 214, may be incident on the micro shutter array at a position corresponding to a micro shutter element 406b. That is, the angular direction or incident angle θ1 of the laser beam directed by the scanner determines the corresponding position or the exact micro shutter element(s) 406b at which the returned laser beam is incident on the micro shutter array. Similarly, in part (b) of FIG. 4, the angular direction 402b or incident angle θ2 of a laser beam at which the scanner of the LiDAR system is pointing at object(s) 212 determines the returned laser beam 404b and the corresponding micro shutter element 406e at which the returned laser beam is incident on the micro shutter array. In part (c) of FIG. 4, the angular direction 402c or incident angle θ3 of a laser beam at which the scanner of the LiDAR system is pointing at object(s) 212 determines the returned laser beam 404c and the corresponding micro shutter element 406h at which the returned laser beam is incident on the micro shutter array. In part (d) of FIG. 4, the angular direction 402d or incident angle θ4 of a laser beam at which the scanner of the LiDAR system is pointing at object(s) 212 determines the returned laser beam 404d and the corresponding micro shutter element 406k at which the returned laser beam is incident on the micro shutter array. That is, when the angular direction or the incident angle at which the scanner of the LiDAR system is pointing at a far-field object is determined, the corresponding micro shutter element(s) at which the returned laser beam is incident on the micro shutter array at is also determined. Since the angular direction or the incident angle at which the scanner of the LiDAR system is pointing at a far-field object at each time point can be predetermined, e.g., determined according to the predefined scanning pattern of the scanner of the LiDAR system, the corresponding micro shutter element(s) at which the returned laser beam is incident on the micro shutter array at each time point may be also determined consequentially. That is, a pattern in which the micro shutter elements are controlled to open may match a scanning pattern in which the emitted laser beams are directed towards the environment (e.g., towards far-field objects), as further described in FIG. 5.

FIG. 5 illustrates a schematic diagram of an exemplary view of sequentially opened micro shutter elements in a micro shutter array, according to embodiments of the disclosure. As illustrated, at one time point during a scanning process, a micro shutter element 502a may be controlled to open since the returned laser beam is incident right on the micro shutter element 502a. As the scanner continuously scans following a predefined pattern (e.g., a two-dimensional scanning pattern with the horizontal scanning as a fast axis and the vertical scanning as a slow axis), the micro shutter element that is controlled to open may continue to shift from 502a along a direction as indicated by the arrowed dotted line 504. For instance, at a next time point of the scanning process, micro shutter element 502b is controlled to open. Meanwhile, micro shutter element 502a is controlled to close at that time point. That is, at each time point, only micro shutter element(s) corresponding to the incident returned laser beam is controlled to open, while the remaining micro shutter elements in the micro shutter array remain closed. Therefore, during the scanning process, the micro shutter elements in the micro shutter array are controlled to open sequentially, following a pattern matching the scanning pattern that the scanner follows. If the scanner of the LiDAR system follows a different scanning pattern (e.g., a two-dimensional scanning pattern with the horizontal scanning as a slow axis and the vertical scanning as a fast axis, or a one-dimensional scanning pattern), the pattern in which the micro shutter elements are controlled to sequentially open may also be changed accordingly. In this way, it can be ensured that only the portion of the micro shutter array corresponding to the returned laser beam be controlled to open at any given time point while all other micro shutter elements remain closed. This then blocks most of the ambient light without affecting the detection of the returned laser beams during a scanning process by the LiDAR system.

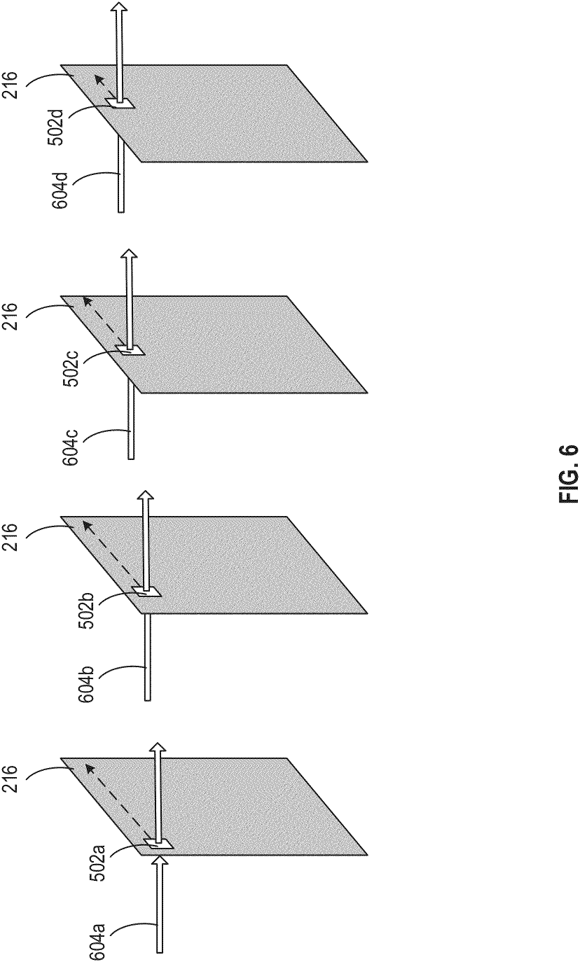

FIG. 6 illustrates a schematic diagram of another exemplary view of sequentially opened micro shutter elements in a micro shutter array, according to embodiments of the disclosure. As illustrated, during a scanning process, the micro shutter elements 502a-502d are controlled to open sequentially, thereby allowing the laser beams 604a-604d returned at different time points to sequentially pass through micro shutter array 216 for detection by the photodetector of the LiDAR system. The pattern in which the micro shutter elements are controlled to open may match the scanning pattern of the LiDAR system, as described above in connection with FIGS. 4-5.

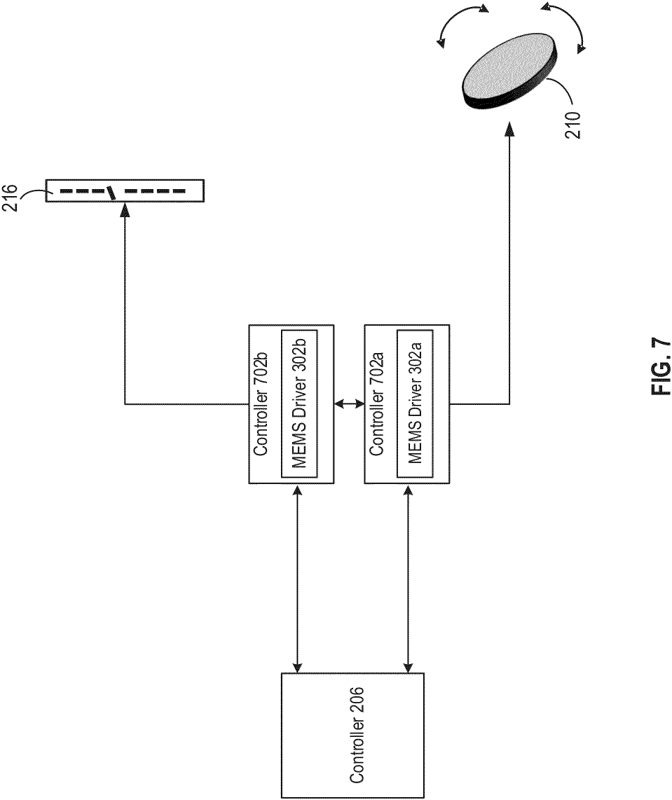

It is to be noted that while only one micro shutter element is controlled to open at one time point in the illustrated FIGS. 4-5, in some embodiments, if the returned laser beam, or more specifically a focused spot, has a size larger than one micro shutter element when the returned laser beam is incident on the micro shutter array, two or more micro shutter elements may be controlled to open simultaneously, to ensure that the returned laser beam passes through the micro shutter element without a signal loss. Regardless of whether a single micro shutter element or more than one micro shutter elements are controlled to open at each time point, given the large number of micro shutter elements in a micro shutter array for the disclosed LiDAR system with a large receiving optics FOV, the majority (e.g., over 99%) of the micro shutter elements in the micro shutter array remain closed, and thus the majority (e.g., over 99%) of the ambient light is blocked. That is, the signal-to-noise ratio may still maintain high, allowing detection of the environment at high accuracy with a large detection range. The specific control process of the micro shutter array to achieve the expected benefits is described more in detail below in FIG. 7.

FIG. 7 illustrates a schematic diagram of an exemplary control mechanism for controlling the micro shutter array, according to embodiments of the present disclosure. As previously described in FIG. 3, scanner 210 of LiDAR system 102 may be driven by a MEMS driver 302a to rotate, to achieve different scanning patterns as described above. In some embodiments, MEMS driver 302a may receive instructions from its integrated controller 702a or controller 206 coupled to MEMS driver 302a, where the instructions may instruct MEMS driver 302a to drive scanner 210 to rotate according to a predefined pattern. In some embodiments, MEMS driver 302a may be a part of controller 702a. In alternative embodiments, there is no controller 702ain the LiDAR system, and MEMS driver 302a may directly communicate with controller 206 to receive instructions from controller 206.

Similarly, a MEMS driver 302amay be coupled to micro shutter array 216, to drive a micro shutter element to open or close. In some embodiments, multiple MEMS drivers 302b may be included in the LiDAR system, where each MEMS driver 302b may control only one or just a few micro shutter elements included in the micro shutter array 216. In some embodiments, different MEMS mechanisms may be employed to drive a micro shutter element to open or close. For instance, a comb drive-based rotation mechanism may be employed to drive a micro shutter element to rotate around a hinge (like a door or window) so as to open or close the micro shutter element. Alternatively, a micro shutter element may be controlled, e.g., by a different comb-drive-based mechanism, to slide behind or in front of another micro shutter element(s), so as to “open” the micro shutter element to allow a returned laser beam to pass through the “hole” opened by the micro shutter element. Other MEMS driving mechanisms to open a micro shutter element are also possible and are contemplated.

Similar to MEMS driver 302a, MEMS driver 302b may be also integrated in a controller 702b and/or coupled to controller 206, which provides instructions to MEMS driver 302b to drive a micro shutter element to open or close during a scanning process. For instance, the instructions may instruct whether and/or when to open/close a specific micro shutter element, and which pattern should follow when multiple micro shutter elements are sequentially opened. Controller 702b (or controller 206 if there is no controller 702b) may communicate with controller 702a (or controller 206 if there is no controller 702a), to identify the scanning pattern that the scanner follows in a scanning process, and then determine the pattern in which the micro shutter elements should be sequentially opened, so that a returned laser beam can timely pass through an opened portion of the micro shutter array. Based on the determined pattern for sequentially opening the micro shutter elements, a corresponding instruction may be generated and provided to MEMS driver 302a, which then drives the micro shutter array to open the micro shutter elements following the determined pattern. That is, through communication between the controllers controlling the operations of the scanner and the micro shutter array, the micro shutter elements may be controlled to open/close timely and sequentially, so as to achieve the filtering function of the micro shutter array.

In some embodiments, to assemble the whole FOV detection signal from the sequentially detected signals, a controller (e.g., controller 206) may record the location information of an opened micro shutter element when the intensity information of the returned laser beam passed through that micro shutter element is detected by the photodetector of the LiDAR system. By combining the location information and the corresponding light intensity information corresponding to each opened micro shutter element during a scanning process, the whole FOV detection signal may be then obtained for detecting far-field objects in the environment.

It is to be noted that, in some embodiments, not all micro shutter elements in a micro shutter array need to be open and/or closed during a scanning process. In some embodiments, the number of micro shutter elements constructed for a micro shutter array may be larger than the number of micro shutter elements required for covering the whole receiving optics FOV in a scanning process. For instance, in the micro shutter array illustrated in FIG. 5, maybe only about 90% of the illustrated micro shutter elements are sequentially opened and closed in a sensing process. It is also to be noted that the exact shape of a micro shutter array may not be as the shape shown in FIG. 5, but can be in other different shapes, such as a circle, square, and an ellipse, etc. In addition, the shape and size of each micro shutter array may also be different. For instance, a micro shutter element may be a circle, an ellipse, a rectangle, a square, etc. The size of a micro shutter element included in the micro shutter array may also vary. In some embodiments, the size of a micro shutter element may depend on the size of a returned laser beam or the size of a focused spot of the LiDAR system. For instance, for an emitted laser beam with a larger divergence, the size of a micro shutter element may be designed to be larger. Other factors that affect the size of a returned laser beam may also be considered. Once properly designed and/or optimized, a micro shutter array may be deployed by the corresponding biaxial scanning LiDAR system for actual applications, e.g., for optical sensing as described below.

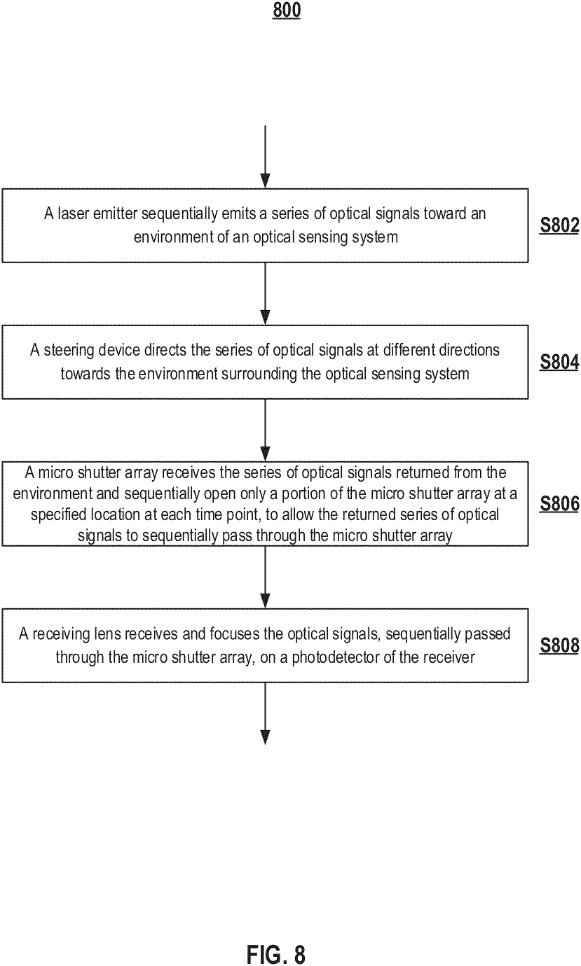

FIG. 8 is a flow chart of an exemplary optical sensing method 800 performed by a LiDAR system containing a micro shutter array, according to embodiments of the disclosure. In some embodiments, method 800 may be performed by various components of LiDAR system 102, e.g., transmitter 202, receiver 204 containing micro shutter array 216, and/or controller 206. In some embodiments, method 800 may include steps S802-S808. It is to be appreciated that some of the steps may be optional. Further, some of the steps may be performed simultaneously, or in a different order than that shown in FIG. 8.

In step S802, an optical source (e.g., laser emitter 208) inside a transmitter of an optical sensing system (e.g., transmitter 202 of LiDAR system 102) may emit a series of optical signals for optical sensing of the environment. Here, the optical signals emitted by the optical source may have a predetermined beam size and divergence. In some embodiments, the emitted optical signals may have a high intensity and a large divergence, to allow detection of the objects in a wide range.

In step S804, a steering device of the optical sensing system (e.g., scanner 210 in transmitter 202 of LiDAR system 102) may steer the emitted optical signals toward the environment surrounding the optical sensing system. The steering device may steer the emitted optical signals according to a predefined pattern, so that different parts of the environment may be scanned over a short period of time. For instance, the emitted optical signals may be directed toward far-field objects in the environment according to a predefined scanning pattern (e.g., a two-dimensional scanning pattern). The objects in the environment may then reflect at least a portion of the optical signals toward the LiDAR system. In some embodiments, the LiDAR system may be biaxial and thus the returned optical signals may be directly directed towards a receiving lens (e.g., receiving lens 214) of the LiDAR system without being reflected by the steering device. The receiving lens may collimate the received optical signals. In some embodiments, to increase the detection range, the receiving lens FOV may be large. Therefore, a certain amount of ambient light may be also received by the receiving lens. The received ambient light may be also collimated by the receiving lens.

In step S806, a micro shutter array (e.g., micro shutter array 216) disposed after the receiving lens may receive the series of optical signals collimated by the receiving lens, where the micro shutter array may sequentially open only a portion of the micro shutter array at a specified location at each time point, to allow the returned series of optical signals to sequentially pass through the micro shutter array. As previously described, the micro shutter array may include a plurality of micro shutter elements, where each of the plurality of micro shutter elements may be in one of an open or closed state, and may include a reflective surface that reflects the ambient light if the micro shutter element is in the closed state. To allow the series of optical signals to pass through the micro shutter array, different portions of the micro shutter array may be sequentially opened, where each opened portion may allow a corresponding returned optical signal to pass through. The exact position at which a portion of the micro shutter array to be opened corresponds to an incident location of a returned optical signal on the micro shutter array. Since the returned series of optical signals follow the predefined scanning pattern when the signals are incident on the micro shutter array, the multiple portions included in the micro shutter array may be also controlled to open sequentially following the scanning pattern, to allow each returned optical signal to pass through each corresponding opened portion of the micro shutter array.

As described above, when receiving the returned optical signals, the receiving lens may also receive the ambient light (unless specified, an optical signal throughout the specification may mean a laser light or an optical signal other than the ambient light). The received ambient light may be also collimated towards the micro shutter array. However, different from the returned optical signals that are incident only on a very small portion (e.g., less than 1%) of the micro shutter array, the received ambient light may be incident on the whole surface of the micro shutter array. Since only a small portion of the micro shutter array is controlled to open at any time point, only a very small portion of the ambient light, if any, may thus pass through the opened portion of the micro shutter array with the returned laser beam, and the majority of the collimated ambient light is blocked by the remaining closed majority portion of the micro shutter array. Therefore, even the receiving lens of the LiDAR system has a large FOV aimed at a large detection range, the signal-to-noise ratio may be maintained high for the disclosed LiDAR system due to the blocked ambient light by the micro shutter array.

In step S808, a photodetector (e.g., photodetector 220) of the LiDAR system may receive the series of optical signals sequentially passed through the micro shutter array. The series of optical signals may be sequentially received by the photodetector. When each optical signal is detected by the photodetector, the location information of the corresponding micro shutter element(s) allowing the pass-through of that optical signal is also received and recorded, e.g., by a controller of the LiDAR system. Therefore, after all the returned optical signals are detected, the detection signal for the entire receiving FOV can be then obtained by combining the sequentially detected signals. The whole FOV detection signal can then be used to generate a frame of image or map for the whole receiving lens FOV during an optical sensing process. The generated frame of an image or map may have a high accuracy due to the filtering effect of the micro shutter array that blocks the noise of the ambient light received by the large FOV receiving lens. The disclosed LiDAR system with a micro shutter array may thus achieve both a large detection range and a high accuracy during an optical sensing process.

Although the disclosure is made using a LiDAR system as an example, the disclosed embodiments may be adapted and implemented to other types of optical sensing systems that use receivers to receive optical signals not limited to laser beams. For example, the embodiments may be readily adapted for optical imaging systems or radar detection systems that use electromagnetic waves to scan objects.

Another aspect of the disclosure is directed to a non-transitory computer-readable medium storing instructions which, when executed, cause one or more processors to perform the methods, as discussed above. The computer-readable medium may include volatile or nonvolatile, magnetic, semiconductor-based, tape-based, optical, removable, non-removable, or other types of computer-readable medium or computer-readable storage devices. For example, the computer-readable medium may be the storage device or the memory module having the computer instructions stored thereon, as disclosed. In some embodiments, the computer-readable medium may be a disc or a flash drive having the computer instructions stored thereon.

It will be apparent to those skilled in the art that various modifications and variations can be made to the disclosed system and related methods. Other embodiments will be apparent to those skilled in the art from consideration of the specification and practice of the disclosed system and related methods.

It is intended that the specification and examples be considered as exemplary only, with a true scope being indicated by the following claims and their equivalents.

What is claimed is:

1. An optical sensing system, comprising:
a laser emitter, configured to sequentially emit a series of optical signals;
a steering device, configured to direct the series of optical signals in different directions towards an environment surrounding the optical sensing system; and
a receiver, configured to receive the series of optical signals returning from the environment, wherein the receiver comprises:
a micro shutter array disposed in a light path of the returning series of optical signals and configured to sequentially open only a portion of the micro shutter array at a specified location at each time point, to allow the returned series of optical signals to sequentially pass through the micro shutter array; and
a photodetector configured to receive the optical signals sequentially passed through the micro shutter array.

2. The optical sensing system of claim 1, wherein the micro shutter array comprises a plurality of micro shutter elements arranged in a two-dimensional array.

3. The optical sensing system of claim 2, wherein the portion of the micro shutter array opened at each time point comprises one or more micro shutter elements.

4. The optical sensing system of claim 3, wherein at each time point a corresponding returning optical signal is incident on the one or more micro shutter elements in the portion of the micro shutter array opened at the time point.

5. The optical sensing system of claim 4, wherein micro shutter elements in a remaining portion of the micro shutter array is closed at the corresponding time point.

6. The optical sensing system of claim 1, wherein the specified location, at which the portion of the micro shutter array is opened at each time point, corresponds to an angular direction at which the steering device is pointing at the corresponding time point.

7. The optical sensing system of claim 1, wherein a plurality of portions included in the micro shutter array are sequentially opened according to a pattern in which the series of optical signals are directed towards the environment.

8. The optical sensing system of claim 7, further comprising one or more controllers coupled to the steering device and the micro shutter array, wherein the one or more controllers determine the pattern in which the series of optical signals are directed towards the environment and the pattern in which the plurality of portions of the micro shutter array are sequentially opened.

9. The optical sensing system of claim 7, wherein the steering device and the receiver have a biaxial arrangement.

10. The optical sensing system of claim 1, wherein the micro shutter array is driven to close or open by a micro-electromechanical system (MEMS) driver coupled to the micro shutter array.

11. An optical sensing method, comprising:
sequentially emitting, by a laser emitter of an optical sensing system, a series of optical signals;
directing, by a steering device of the optical sensing system, the series of optical signals in different directions towards an environment surrounding the optical sensing system;
receiving the series of optical signals returned from the environment, by a micro shutter array disposed in a light path of the returning series of optical signals, wherein the micro shutter array sequentially opens only a portion of the micro shutter array at a specified location at each time point, to allow the returned series of optical signals to sequentially pass through the micro shutter array; and
receiving, by a photodetector, the optical signals sequentially passed through the micro shutter array.

12. The optical sensing method of claim 11, wherein the micro shutter array comprises a plurality of micro shutter elements arranged in a two-dimensional array.

13. The optical sensing method of claim 12, wherein the portion of the micro shutter array opened at each time point comprises one or more micro shutter elements.

14. The optical sensing method of claim 13, wherein receiving the series of optical signals by the micro shutter array further comprises:
controlling the one or more micro shutter elements in each portion of the micro shutter array to open at a time point when a corresponding returning optical signal is incident on the portion of the micro shutter array.

15. The optical sensing method of claim 14, wherein receiving the series of optical signals by the micro shutter array further comprises:
controlling micro shutter elements in a remaining portion of the micro shutter array to remain closed at the corresponding time point.

16. The optical sensing method of claim 11, further comprising:
controlling, by one or more controllers coupled to the steering device and the micro shutter array, the steering device to direct the series of optical signals towards the environment according to a first pattern and the micro shutter array to sequentially open a plurality of portions included in the micro shutter array according to a second pattern.

17. The optical sensing method of claim 16, wherein the second pattern in which a plurality of portions of the micro shutter array are sequentially opened corresponds to the first pattern in which the series of optical signals are directed towards the environment.

18. The optical sensing method of claim 11, wherein the specified location, at which the portion of the micro shutter array is opened at each time point, corresponds to an angular direction at which the steering device is pointing at the corresponding time point.

19. A receiver of an optical sensing system, comprising:
a micro shutter array disposed in a light path of returning series of optical signals and configured to sequentially open only a portion of the micro shutter array at a specified location at each time point, to allow the returned series of optical signals to sequentially pass through the micro shutter array; and
a photodetector, configured to receive the optical signals sequentially passed through the micro shutter array.

20. The receiver of claim 19, wherein the micro shutter array comprises a plurality of micro shutter elements arranged in a two-dimensional array.
